(19) United States
(12) Patent Application Publication
(10) Pub. No.: US 2024/0074058 A1
(43) Pub. Date: Feb. 29, 2024

(54) MODULE BOARD AND SEMICONDUCTOR MODULE HAVING THE SAME

(71) Applicant: SAMSUNG ELECTRONICS CO., LTD., Suwon-si (KR)

(72) Inventors: JAEKWANG LEE, Suwon-si (KR); HYUN A LEE, Suwon-si (KR); DOHYUNG KIM, Suwon-si (KR); DONGMIN JANG, Suwon-si (KR); JINWOO JANG, Suwon-si (KR)

(21) Appl. No.: 18/164,748

(22) Filed: Feb. 6, 2023

(30) Foreign Application Priority Data
Aug. 24, 2022 (KR) 10-2022-0106453

(51) Int. Cl. H05K 1/11; H05K 3/18; H05K 3/28

(52) U.S. Cl. CPC H05K 1/117; H05K 3/18; H05K 3/28; H05K 1/09; H05K 2201/032; H05K 2201/0347; H05K 2201/09381; H05K 2201/099

(57) ABSTRACT

A module board includes a substrate having a wire pattern on a surface, a protection layer covering the surface of the substrate so as to expose one edge region of the substrate surface, and a plurality of tab terminals connected to the wire pattern and arranged on one edge region. Each tab terminal has a width larger than a width of the wire pattern. Each tab terminal has a pattern layer. A protection layer is on the pattern layer at a region where each tab terminal is connected to the wire pattern, and a plating layer is on a remainder of the pattern layer.

### CROSS-REFERENCE TO RELATED APPLICATION

This application claims priority under 35 U.S.C. § 119 to Korean Patent Application No. 10-2022-0106453 filed in the Korean Intellectual Property Office on Aug. 24, 2022, the entire contents of which are incorporated herein by reference.

### BACKGROUND

### (a) Field

The present disclosure relates to module boards and semiconductor modules including the same.

### (b) Description of the Related Art

A module board used for a semiconductor module has tab terminals on the edge of a substrate. The tab terminals facilitate an electrical signal connection and are inserted into a socket and are electrically connected to electronic components, including the socket.

For environmental reasons, efforts are being made to reduce gas discharge generated in the manufacturing process of semiconductor modules. In relation to this, cooling of semiconductor modules through external ventilation is being utilized to reduce power consumption. Unfortunately, corrosion may occur in corrodible materials such as silver (Ag) and copper (Cu) due to corrosive material that can inflow during external ventilation.

In particular, tab terminals of conventional module boards have regions that may be vulnerable to corrosion. Defects, such as wire pattern breakage, may occur due to Cu corrosion in these regions.

### SUMMARY

One aspect is to provide module boards that may prevent corrosion at the pattern neck, which is a weak region susceptible to corrosion at a tab terminal.

Another aspect is to provide semiconductor modules with improved life-span reliability by preventing pattern defects caused by corrosion.

A module board according to an embodiment includes a substrate having a surface, a wire pattern on the substrate surface, a protection layer on the substrate surface and configured to expose an edge region of the substrate surface. A plurality of tab terminals are on the edge region in adjacent, spaced apart relationship and are connected to the wire pattern. Each tab terminal has a width that is larger than a width of a portion of the wire pattern to which each tab terminal is connected. Each tab terminal includes a pattern layer, and the protection layer is on a portion of the pattern layer at a region where each tab terminal is connected to the wire pattern, and a plating layer is on a remaining portion of the pattern layer.

The plating layer may include a first plating layer on the pattern layer and a second plating layer on the first plating layer.

The boundary line between the protection layer and the plating layer may extend in the width direction of each of the tab terminals.

The protection layer may include a first protection layer on the wire pattern, and a second protection layer on the region where each tab terminal is connected to the wire pattern.

Each tab terminal may include an overlapping region where the protection layer extends over a portion of the plating layer.

In the overlapping region, the protection layer may be on a portion of the second plating layer.

In the overlapping region, the protection layer may be on a portion of the first plating layer.

At each tab terminal, an end of the protection layer may abut an end of the second plating layer.

A width of each tab terminal in a region where each tab terminal is connected to the wire pattern may gradually increase in a direction toward a free end of the substrate edge region.

For each tab terminal, the protection layer may conform to a shape of a region where each tab terminal is connected to the wire pattern.

The pattern layer may include copper, and the plating layer may include at least one of nickel and gold.

A module board according to an embodiment includes a substrate having a surface, a wire pattern on the substrate surface, a protection layer on the wire pattern, and a plurality of tab terminals on an edge portion of the substrate surface in adjacent, spaced apart relationship. The tab terminals are connected to the wire pattern and each tab terminal has a width that is larger than a width of a portion of the wire pattern to which each tab terminal is connected. The protection layer is on a portion of each tab terminal at a region where each tab terminal is connected to the wire pattern, and a plating layer is on a remaining portion of each tab terminal.

Each tab terminal includes a pattern layer and the plating layer is on a portion of the pattern layer.

The pattern layer may be completely covered by the protection layer and the plating layer.

The boundary line between the protection layer and the plating layer may extend in a width direction of each of the tab terminals.

The protection layer may include a first protection layer on the wire pattern, a second protection layer on the region where each tab terminal is connected to the wire pattern, and the second protection layer may be on the first protection layer and the plating layer.

Each tab terminal may include an overlapping region where the protection layer extends over the plating layer. The plating layer may include a first plating layer on the pattern layer and a second plating layer on the first plating layer. The protection layer may be on the second plating layer in the overlapping region.

Each tab terminal may include an overlapping region in which the protection layer extends over the plating layer. The plating layer may include a first plating layer on the pattern layer and a second plating layer on the first plating layer. The protection layer may be on the first plating layer in the overlapping region.

A semiconductor module according to an embodiment includes a module board having a substrate that includes a surface and a wire pattern on the substrate surface. A protection layer covers the wire pattern on the substrate surface, and a plurality of tab terminals are on an edge region of the substrate surface in adjacent, spaced apart relationship. The tab terminals are connected to the wire pattern. A plurality of semiconductor elements are on the substrate surface of the module board and are connected to the wire pattern. Each tab terminal has a width that is larger than a width of a portion of the wire pattern to which each tab terminal is connected. The protection layer is on a portion of each tab terminal and a plating layer is on a remaining portion of each tab terminal.

The protection layer is on each tab terminal at a region where each tab terminal is connected to the wire pattern, and a boundary between the protection layer and the plating layer may extend in a width direction of each of the tab terminals.

According to an embodiment, by covering the pattern neck of the tab terminal with the protection layer, it is possible to prevent corrosion of the pattern neck.

In addition, life-span reliability may be increased by preventing pattern defects caused by corrosion.

### BRIEF DESCRIPTION OF THE DRAWINGS

FIG. 1 is a front view of a semiconductor module according to an embodiment.

FIG. 2 is an enlarged view of a portion A of FIG. 1.

FIG. 3 is a cross-sectional view of a first embodiment.

FIG. 4 is a cross-sectional view of a second embodiment.

FIG. 5 is a front view of a second embodiment.

FIG. 6 is a cross-sectional view of a third embodiment.

FIG. 7 to FIG. 9 are views to explain a manufacturing process of a third embodiment.

FIG. 10 is a cross-sectional view of a fourth embodiment.

FIG. 11 to FIG. 13 are views to explain a manufacturing process of a fourth embodiment.

FIG. 14 and FIG. 15 are views showing a modified form of an embodiment.

### DETAILED DESCRIPTION

Hereinafter, an embodiment will be described more fully with reference to the accompanying drawings for a person of ordinary skill to easily implement the present invention. As those skilled in the art would realize, the described embodiments may be modified in various different ways, all without departing from the scope of the present invention.

The drawings and description are to be regarded as illustrative in nature and not restrictive. Like reference numerals designate like elements throughout the specification.

Because the size and thickness of each configuration shown in the drawings are arbitrarily shown for better understanding and ease of description, the present invention is not limited thereto.

Throughout the specification, when it is described that a part is “connected (in contact with, coupled)” to another part, the part may be “directly connected” to the other element or “connected” to the other part through a third part. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Hereinafter, a module board according to an embodiment and a semiconductor module including the same will be described with reference to accompanying drawings.

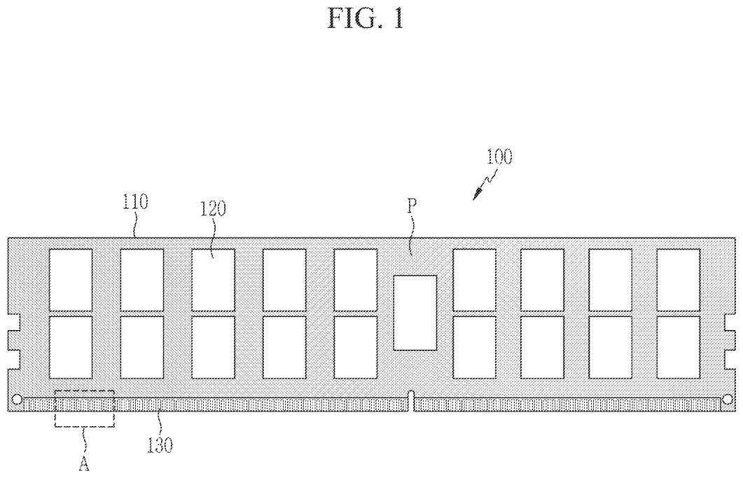

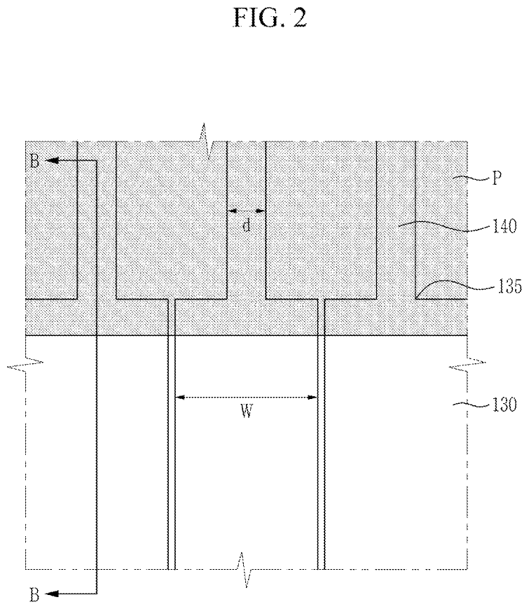

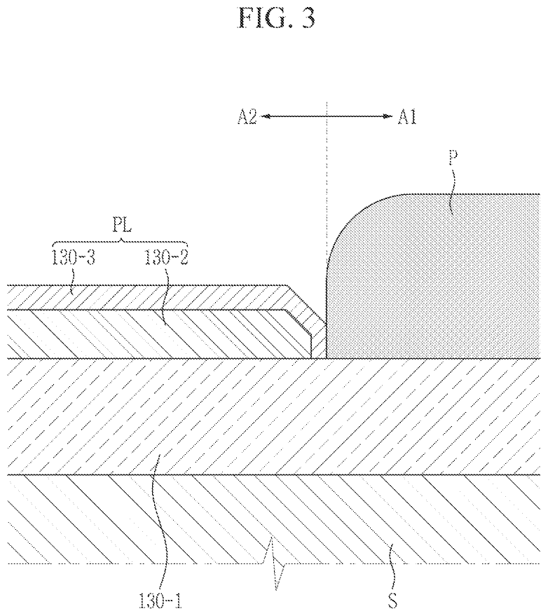

FIG. 1 is a front view of a semiconductor module 100 according to an embodiment, FIG. 2 is an enlarged view of a portion A of FIG. 1, and FIG. 3 is a cross-sectional view of a first embodiment. FIG. 3 is a cross-sectional view of a direction B-B in FIG. 2.

Referring to FIG. 1, a semiconductor module 100 includes a plurality of semiconductor elements 120, and a module board 110 to which a plurality of semiconductor elements 120 are mounted.

According to an embodiment, the semiconductor module 100 may be a memory module, and for example, may be at least one memory module selected from a DIMM (Dual Inline Memory Module), a SO-DIMM (Small Outline Dual Inline Memory Module), or an Unbuffered-DIMM or FB-DIMM (Fully Buffered Dual Inline Memory Module), but is not limited thereto.

The semiconductor elements 120 may be provided on the surface of the module board 110 and connected to a wire pattern formed on the surface of the module board 110. According to an embodiment, the semiconductor element 120 may include a memory element, for example, at least one memory element selected from a DRAM (Dynamic Random Access Memory), an SRAM (Static Random Access Memory), a PRAM (Phase Random Access Memory), an RRAM (Resistive Random Access Memory), an EEPROM (Electrically Erasable Programmable Read-Only Memory), or a flash memory, but is not limited thereto.

The module board 110 includes a substrate S (FIG. 3), a protection layer P covering the surface of the substrate, and a plurality of tab terminals 130 arranged in one edge region of the substrate. According to an embodiment, the module board 110 may include a flexible printed circuit (FPC) PCB.

The substrate S may have a wire pattern 140 on the surface. In addition, although not shown in the drawing, a plurality of stacked wiring layers and a via may be included. For example, the substrate S could have an approximately rectangular shape with four corners, but is not limited thereto.

The protection layer P is a layer to protect the wire pattern 140 by covering the surface of the substrate S, and covers the wire pattern 140 so that the wire pattern 140 is not exposed.

According to an embodiment, the protection layer P may include a PSR (Photo Solder Resist). For example, it may be formed through a process of printing a PSR ink on the surface of the substrate S before mounting the semiconductor elements 120. The protection layer P may be formed in a region where an element component is not mounted.

According to an embodiment, the protection layer P may be formed such that one edge region of the substrate S surface is exposed. That is, the protection layer P may not be formed in one edge region in which the tab terminal 130, which is described below, is positioned. Accordingly, one edge region of the substrate S surface may be exposed from the protection layer P.

A plurality of tab terminals 130 are arranged on one edge region of the substrate surface where the protection layer P is not formed. A plurality of tab terminals 130 are parts that are configured to be fastened to a socket of an electronic part to be electrically connected to the electronic part and may be arranged on both surfaces of the substrate S. Also, since a plurality of tab terminals 130 must be connected to the socket, they may be exposed from the protection layer P. A plurality of tab terminals 130 may be connected to a wire pattern 140 formed on the surface of the substrate S.

Referring to FIG. 2, each of a plurality of tab terminals 130 has a width W that is larger than the line width d of the wire pattern 140 and may be partially covered by the protection layer P. In addition, it has a form that is extended towards the edge of the substrate S, and may have a form of an approximate rectangular shape. That is, referring to FIG. 1, a plurality of tab terminals 130 may be arranged side by side at regular intervals with each other.

Since each tab terminal 130 is directly connected to the wire pattern 140 while having the larger width than the wire pattern 140, the tab terminal 130 may include a pattern neck 135 that is a connection part with the wire pattern 140. The pattern neck 135 is a portion with a width that is less than the width W of the tab terminal 130, which may be vulnerable to damage. For example, a corrosion-causing gas may be penetrated into the interface between a plating layer PL covering a pattern layer 130-1 described below and the protection layer P, so that the pattern layer 130-1 of the pattern neck 135 having the relatively small width may be easily corroded and broken. Thus, according to an embodiment, since one region (the region far from the substrate edge) including the connection part with the wire pattern at the tab terminal 130 is covered by the protection layer P, the pattern neck 135 of the vulnerable part may be protected by the protection layer P.

As shown in FIG. 3, a region covered by the protection layer on the tab terminal 130 is defined by A1 (hereinafter, ‘a covered region’), and a region exposed and not covered by the protection layer P is defined by A2 (hereinafter, ‘an exposed region’).

Referring to FIG. 2 and FIG. 3, each tab terminal 130 may be formed of a plurality of layers, and according to an embodiment, may include the pattern layer 130-1 and the plating layer PL.

The pattern layer 130-1 is a layer that is directly connected to the wire pattern 140 and may be extended from the wire pattern 140. The pattern layer 130-1 may be formed on the substrate S in the same process as the wire pattern 140 and may be integral to the wire pattern 140. It may also be made of the same material as the wire pattern 140 and may include one metal or an alloy of the metal. For example, the pattern layer 130-1 may include copper (Cu).

The plating layer PL is a layer plated on the pattern layer 130-1 and covers the region not covered by the protection layer P at the tab terminal 130. That is, the plating layer PL covers the region A2 that is exposed from the protection layer P on the tab terminal 130.

The plating layer PL may include a first plating layer 130-2 on the pattern layer 130-1, and a second plating layer 130-3 on the first plating layer 130-2. The plating layer PL may be formed by plating the upper part of the pattern layer 130-1, for example, the first plating layer 130-2 and the second plating layer 130-2 may be sequentially formed over the pattern layer 130-1 through a commonly known plating process such as the electroplating process. The plating layer PL is made up of a metal with very low resistance, which allows the tab terminal 130 to have low resistance. According to an embodiment, the plating layer PL may include at least one of nickel (Ni) and gold (Au). For example, the first plating layer 130-2 may be plated with nickel (Ni), and the second plating layer 130-3 may be plated with gold (Au).

According to an embodiment, the pattern layer 130-1 may be completely covered by the protection layer P and the plating layer PL so that there is no region exposed to the outside. Accordingly, it is possible to prevent the penetration of the corrosion-causing gas into the interface of the plating layer PL and the protection layer P. Hereinafter, various forms of the embodiment will be described in conjunction with the drawings.

According to a first embodiment, the pattern layer 130-1 is covered by the protection layer P and the plating layer PL, and referring to FIG. 2 and FIG. 3, the boundary line of the protection layer P and the plating layer PL may extend in the width direction of each tab terminal 130. That is, the boundary line of the protection layer P and the plating layer PL is positioned on the tab terminal 130 having the larger width W that is not the region having the small width d such as the pattern neck 135, also the region A2 exposed from the protection layer P is covered by the plating layer PL, thereby preventing the damage of the tab terminal 130 due to the corrosion.

In the case of the first embodiment, like a manufacturing process of a general flexible printed circuit (FPC), the wire pattern 140 and the pattern layer 130-1 are formed on the substrate S, the protection layer P is then formed to cover one region of the wire pattern 140 and the pattern layer 130-1, and then the upper part of the exposed region A2 of the pattern layer 130-1 is plated with the first plating layer 130-2 and the second plating layer 130-3 through the plating process.

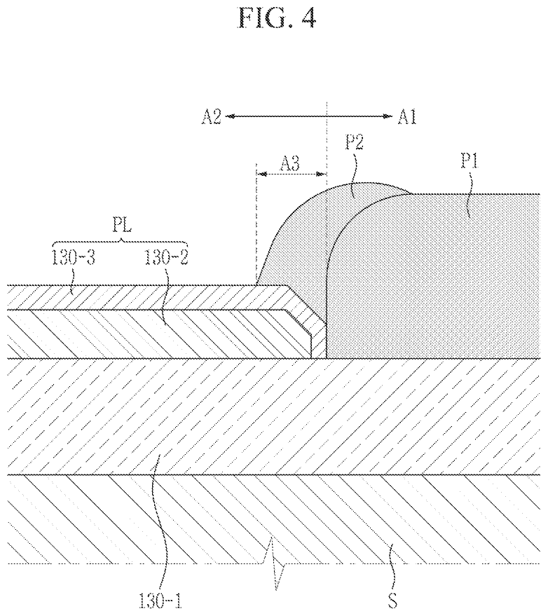

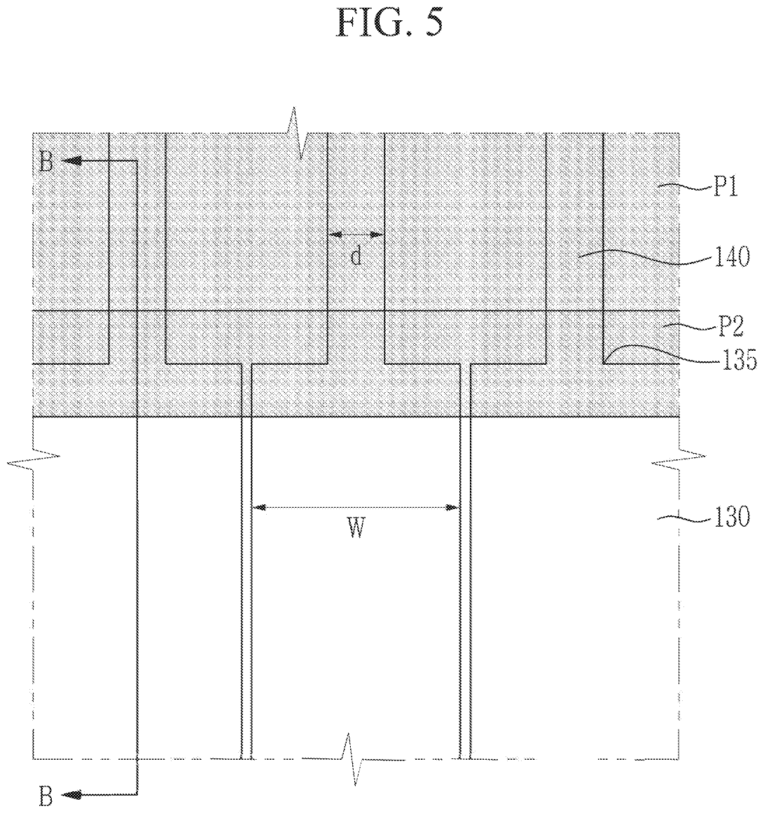

FIG. 4 is a cross-sectional view of a second embodiment, and FIG. 5 is a front view of a second embodiment. FIG. 4 is the drawing showing a cross-sectional view of a direction B-B of FIG. 5.

As shown in FIG. 4 and FIG. 5, according to the second embodiment, the protection layer partially covering the tab terminal 130 may include a first protection layer P1 and a second protection layer P2. That is, the first protection layer P1 may cover the wire pattern 140 that is not the tab terminal 130, and the second protection layer P2 may cover the pattern neck 135 of the tab terminal 130. If the tab terminal 130 is exposed and the wire pattern 140 is covered with only the first protection layer P1, and the boundary between the first protection layer P1 and the plating layer PL may be positioned on the wire pattern 140 with the small line width, and in this case, the gas causing the corrosion may penetrate the boundary between the first protection layer P1 and the plating layer PL. To prevent this, according to the second embodiment, the second protection layer P2 may cover the boundary between the first protection layer P1 and the plating layer PL, for example, the connection part (the pattern neck)135 of the tab terminal 130 and the wire pattern 140. The second protection layer P2 is in both regions A1 and A2, as illustrated in FIG. 4. Region A3 in FIG. 4 indicates the portion of region A2 into which the second protection layer P2 extends. Region A3 may be referred to as an overlapping region. Accordingly, the pattern layer 130-1 may be completely covered by the first and second protection layers P1 and P2, and the plating layer PL.

In the case of the second embodiment, the wire pattern 140 and the pattern layer 130-1 may be formed on the substrate S, and then the first protection layer P1 may be formed to cover the wire pattern 140, the upper part of the exposed region A2 of the pattern layer 130-1 is plated with the first plating layer 130-2 and the second plating layer 130-3 through the plating process, and then the part between the first protection layer P1 and the second plating layer 130-2 may be plated with the second protection layer P2, thereby being manufactured.

The second protection layer P2 may be formed of the same material as the first protection layer P1. According to an embodiment, the second protection layer P2 may be formed of PSR. However, it is not limited thereto, and the second protection layer P2 may be made of a resin and may include an epoxy resin, a thermosetting resin, a UV-curing resin, and an insulating material.

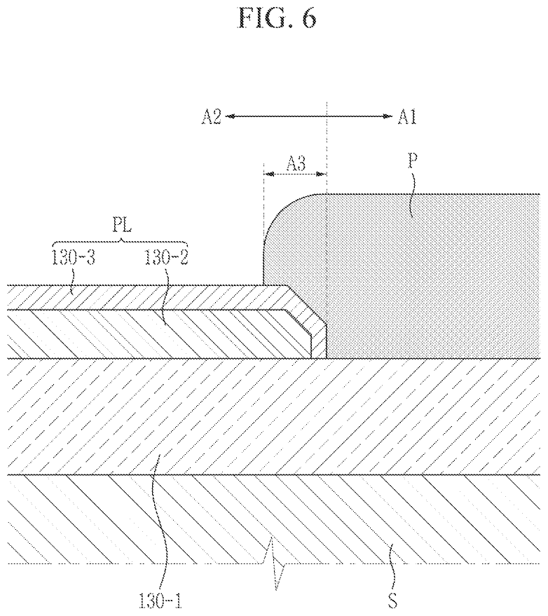

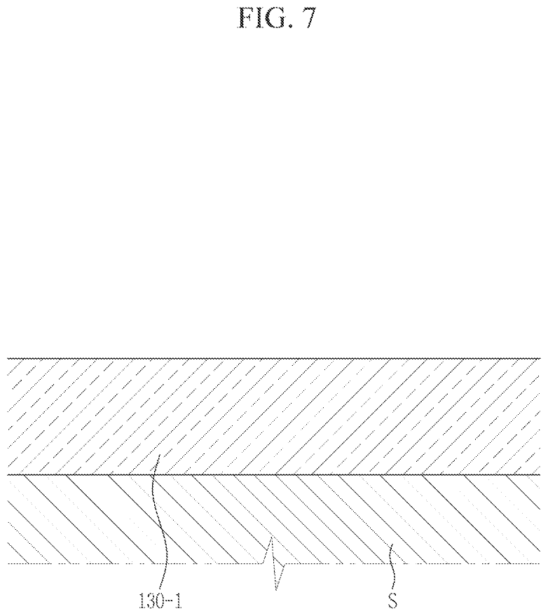

FIG. 6 is a cross-sectional view of a third embodiment, and FIG. 7 to FIG. 9 are views to explain a manufacturing process of a third embodiment. FIG. 6 to FIG. 9 show the cross-sectional view of the direction B-B of FIG. 2.

As shown in FIG. 6 to FIG. 9, according to the third embodiment, each tab terminal 130 may include an overlapping region A3 where a protection layer P and a plating layer PL are overlapped (in the stacked direction) on a pattern layer 130-1. Referring to FIG. 6, in the overlapping region A3, the first plating layer 130-2 and the second plating layer 130-3 may be sequentially accumulated on the pattern layer 130-1, and the protection layer P may be stacked on the second plating layer 130-3. That is, in the overlapping region A3, the first plating layer 130-2, and the second plating layer 130-3 may be covered by the protection layer P. Accordingly, the pattern layer 130-1 may be completely covered by the protection layer P and the plating layer PL. As such, the boundary where the second plating layer 130-3 and the protection layer P abut is covered by the portion of the protection layer P that extends into the overlapping region A3.

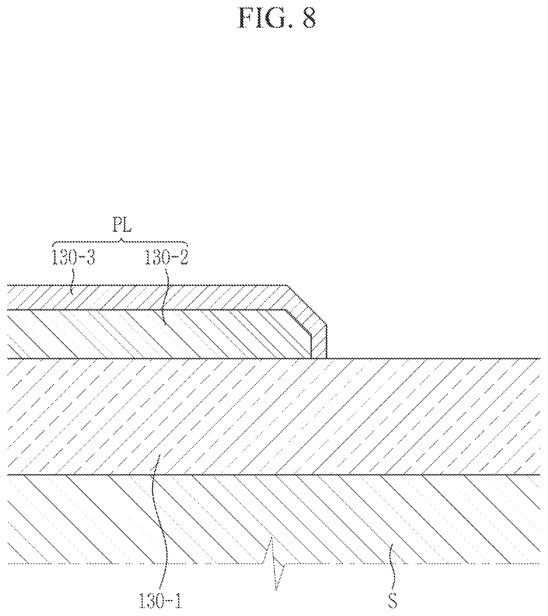

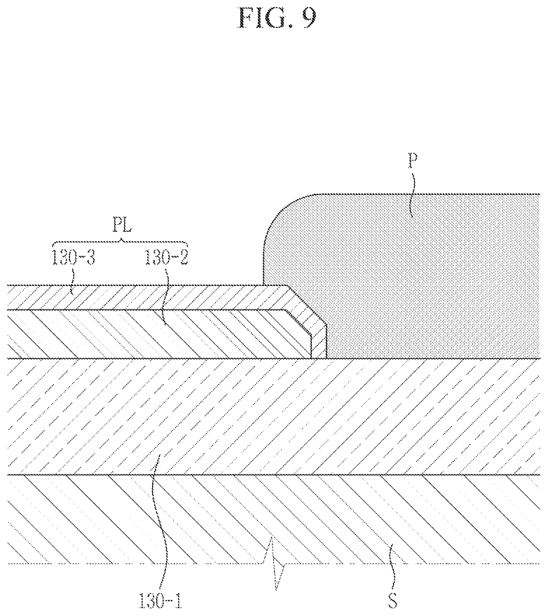

In the case of the third embodiment, the wire pattern 140 and the pattern layer 130-1 are formed on the substrate S (referring to FIG. 7), and then the plating layer PL is formed, and in this case, the first plating layer 130-2 and the second plating layer 130-3 are sequentially formed (referring to FIG. 8). At this time, the regions other than the region to form the plating layer PL are masked so that only the plating layer PL is formed on the necessary regions. The protection layer P may then be formed to cover the wire pattern 140 of the substrate surface, but may be fabricated by covering the pattern layer 130-1 (referring to FIG. 9) so that the protection layer P overlaps with a portion of the plating layer PL.

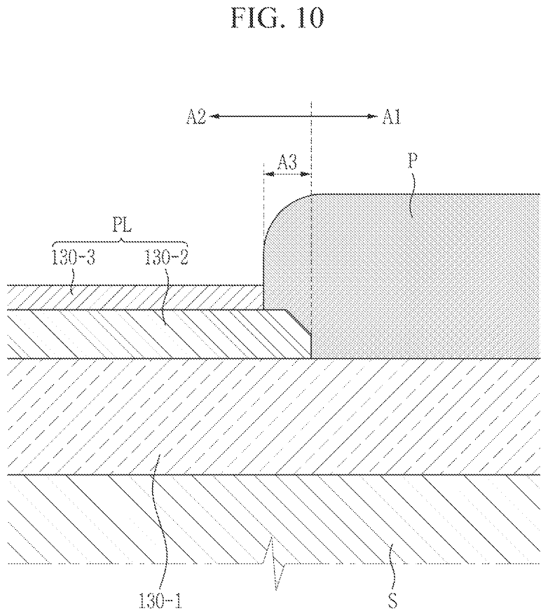

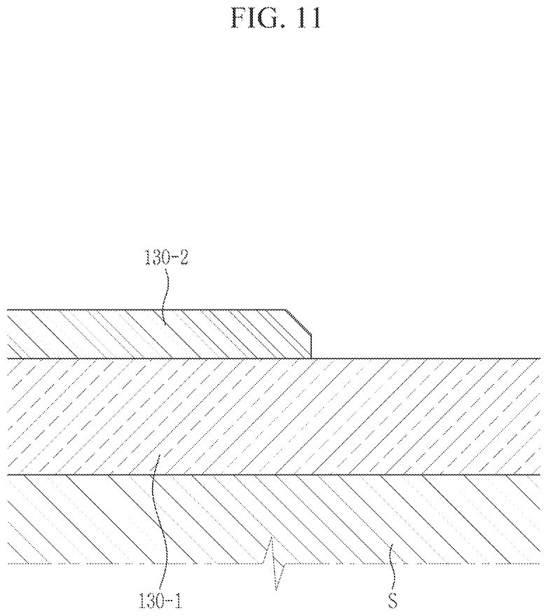

FIG. 10 is a cross-sectional view of a fourth embodiment, and FIG. 11 to FIG. 13 are views to explain a manufacturing process of a fourth embodiment. FIG. 10 to FIG. 13 are the cross-sectional view in the direction B-B of FIG. 2.

As shown in FIG. 10 to FIG. 13, according to the fourth embodiment, each tab terminal 130 may include an overlapping region A3 where a protection layer P and a first plating layer 130-2 are overlapped (in the stacked direction) on the pattern layer 130-1. Referring to FIG. 10, in the overlapping region A3, the first plating layer 130-2 may be stacked on the pattern layer 130-1, and the protection layer P may be stacked directly on the first plating layer 130-2. In the first plating layer 130-2, the region that is not covered by the protection layer P may be covered by the second plating layer 130-3. Here, the end of the protection layer P may be in contact with the end of the second plating layer 130-3. That is, in the overlapping region A3, the first plating layer 130-2 is covered by the protection layer P. Also, the boundary surface of the second plating layer 130-3 and the protection layer P may be positioned on the first plating layer 130-2. Accordingly, the pattern layer 130-1 may be completely covered by the protection layer P and the plating layer PL. As such, the boundary where the first plating layer 130-2 and the protection layer P abut is covered by the portion of the protection layer P that extends into the overlapping region A3.

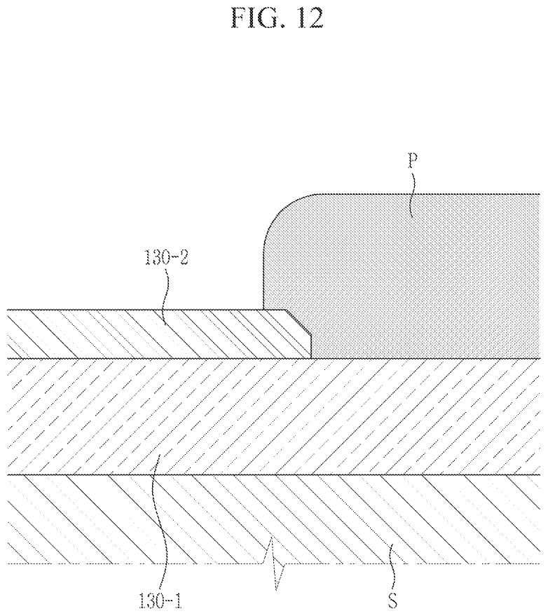

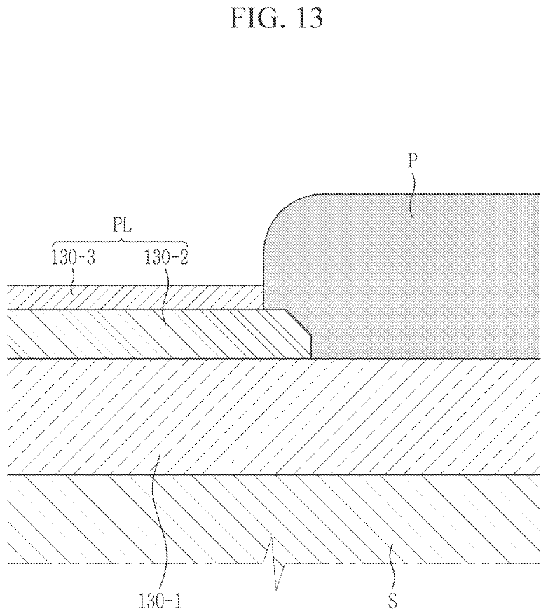

In the case of the fourth embodiment, the wire pattern 140 and the pattern layer 130-1 are formed on the substrate S, and then the first plating layer 130-2 is formed on the pattern layer 130-1 (referring to FIG. 11). At this time, the regions other than the region to form the first plating layer 130-2 are masked so that only the first plating layer 130-2 is formed in the necessary regions. The protection layer P is then formed to cover the wire pattern 140 of the substrate surface, but the protection layer P covers the pattern layer 130-1 to overlap a portion of the first plating layer 130-2 (referring to FIG. 12). Next, the second plating layer 130-3 is formed to cover the region that is not covered by the protection layer P on the first plating layer 130-2 (referring to FIG. 13).

Hereinafter, a modified form of the tab terminal portion and the protection layer from the various embodiments described above will be described as an example.

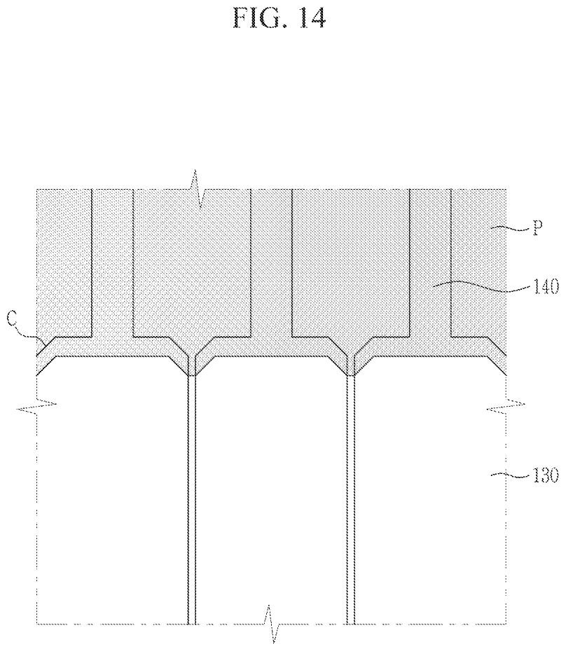

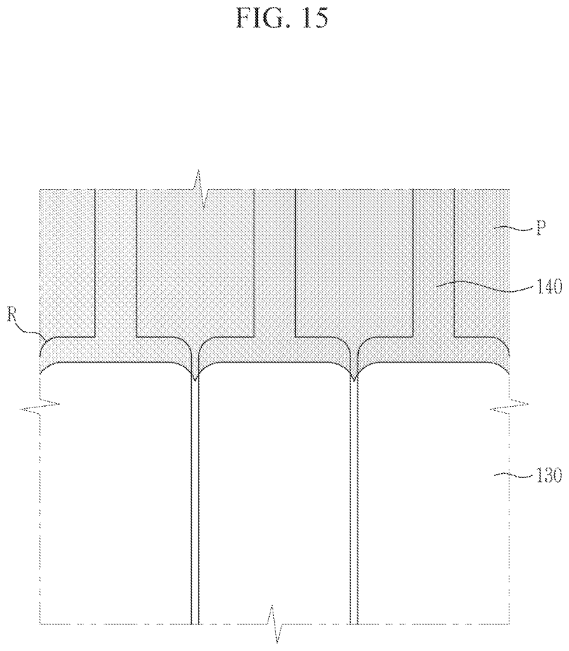

FIG. 14 and FIG. 15 are views showing a modified form of an embodiment.

As mentioned above, each tab terminal 130 is extended towards the edge of the substrate and may have the form of an approximately rectangular shape. Referring to FIG. 14 and FIG. 15, each tab terminal 130 may have a shape in which the connection part with the wire pattern 140 is extended and the width thereof is gradually increased. That is, it may have the shape in which the width is gradually increased as it is extended in the direction away from the pattern neck of the tab terminal 130 and then is maintained constant. If the wire pattern 140 connected to a plurality of tab terminals 130 has a complex and curved shape, interference may occur between the tab terminal 130 and the adjacent wire pattern 140, wherein the tab terminal 130 has the form of gradually increasing in the width direction in the region adjacent to the wire pattern 140, thereby preventing the aforementioned interference.

For example, as shown in FIG. 14, in the tab terminal 130, two vertices adjacent to the wire pattern 140 may be chamfered to have a slope portion C.

Further, as shown in FIG. 15, in the tab terminal 130, two vertices adjacent to the wire pattern 140 may be round-machined to have a circular arc portion R.

According to an embodiment, the shape of the protection layer P in the covered region (A1, referring to FIG. 3, etc.) of each tab terminal 130 may cover the tab terminal 130 to correspond to the shape of the connection part with the wire pattern 140 of the tab terminal 130. For example, as shown in FIG. 14, in the case of the tab terminal 130 having the slope portion C, the protection layer P covering the tab terminal 130 may also have the shape corresponding to the slope portion C. Also, as shown in FIG. 15, in the case of the tab terminal 130 of the circular arc portion R, the protection layer P covering the tab terminal 130 may also have the shape corresponding to the circular arc portion R.

While this disclosure has been described in connection with what is presently considered to be practical embodiments, it is to be understood that the invention is not limited to the disclosed embodiments. On the contrary, it is intended to cover various modifications and equivalent arrangements included within the scope of the appended claims.

### DESCRIPTION OF SYMBOLS

100 semiconductor module
110 module board
120 semiconductor element
130 tab terminal
130-1 pattern layer
130-2 first plating layer
130-3 second plating layer
140 wire pattern
S substrate
P protection layer
PL plating layer

What is claimed is:

1. A module board comprising:
a substrate comprising a surface;
a wire pattern on the substrate surface;
a protection layer on the substrate surface and configured to expose an edge region of the substrate surface; and
a plurality of tab terminals on the edge region of the substrate surface in adjacent, spaced apart relationship, wherein the plurality of tab terminals are connected to the wire pattern,
wherein each tab terminal has a width that is larger than a width of a portion of the wire pattern to which each tab terminal is connected, wherein each tab terminal comprises a pattern layer, wherein the protection layer is on a portion of the pattern layer at a region where each tab terminal is connected to the wire pattern, and wherein a plating layer is on a remaining portion of the pattern layer.

2. The module board of claim 1, wherein
the plating layer comprises a first plating layer on the pattern layer and a second plating layer on the first plating layer.

3. The module board of claim 1, wherein
a boundary between the protection layer and the plating layer extends in a width direction of each of the plurality of tab terminals.

4. The module board of claim 1, wherein
the protection layer comprises:
a first protection layer on the wire pattern; and
a second protection layer on a portion of the first protection layer.

5. The module board of claim 2, wherein
each tab terminal comprises a region where the protection layer extends over a portion of the plating layer.

6. The module board of claim 5, wherein
the protection layer is on a portion of the second plating layer.

7. The module board of claim 5, wherein
the protection layer is on a portion of the first plating layer.

8. The module board of claim 7, wherein
at each tab terminal, an end of the protection layer abuts an end of the second plating layer.

9. The module board of claim 1, wherein
a width of each tab terminal in the region where each tab terminal is connected to the wire pattern gradually increases in a direction toward a free end of the substrate edge region.

10. The module board of claim 9, wherein
for each tab terminal, the protection layer conforms to a shape of the region where each tab terminal is connected to the wire pattern.

11. The module board of claim 1, wherein
the pattern layer comprises copper, and
the plating layer comprises at least one of nickel and gold.

12. A module board comprising:
a substrate comprising a surface;
a wire pattern on the substrate surface;
a protection layer on the wire pattern; and
a plurality of tab terminals on an edge region of the substrate surface in adjacent, spaced apart relationship, wherein the plurality of tab terminals are connected to the wire pattern, wherein each tab terminal has a width that is larger than a width of a portion of the wire pattern to which each tab terminal is connected, wherein the protection layer is on a portion of each tab terminal at a region where each tab terminal is connected to the wire pattern, and wherein a plating layer is on a remaining portion of each tab terminal.

13. The module board of claim 12, wherein
each tab terminal comprises a pattern layer, and wherein the plating layer is on a portion of the pattern layer.

14. The module board of claim 13, wherein
the pattern layer is completely covered by the protection layer and the plating layer.

15. The module board of claim 14, wherein
a boundary between the protection layer and the plating layer extends in a width direction of each of the plurality of tab terminals.

16. The module board of claim 14, wherein
the protection layer comprises:
a first protection layer; and
a second protection layer, and
wherein the second protection layer is on a portion of the first protection layer and the plating layer.

17. The module board of claim 14, wherein
each tab terminal comprises an overlapping region where the protection layer extends over the plating layer,
the plating layer comprises a first plating layer on the pattern layer and a second plating layer on the first plating layer, and
the protection layer is on a portion of the second plating layer in the overlapping region.

18. The module board of claim 14, wherein
each tab terminal comprises an overlapping region where the protection layer extends over the plating layer,
the plating layer comprises a first plating layer on the pattern layer and a second plating layer on the first plating layer, and
the protection layer is on a portion of the first plating layer in the overlapping region.

19. A semiconductor module comprising:
a module board comprising:
a substrate comprising a surface;
a wire pattern on the substrate surface;
a protection layer on the wire pattern; and
a plurality of tab terminals on an edge region of the substrate surface in adjacent, spaced apart relationship, wherein the plurality of tab terminals are connected to the wire pattern; and
a plurality of semiconductor elements on the substrate surface and connected to the wire pattern,
wherein each tab terminal has a width that is larger than a width of a portion of the wire pattern to which each tab terminal is connected, and wherein the protection layer is on a portion of each tab terminal, and wherein a plating layer on a remaining portion of each tab terminal.

20. The semiconductor module of claim 19, wherein
the protection layer is on each tab terminal at a region where each tab terminal is connected to the wire pattern, and
a boundary between the protection layer and the plating layer extends in a width direction of each of the plurality of tab terminals.
